(19) United States
(12) Patent Application Publication
(10) Pub. No.: US 2013/0042904 A1
(43) Pub. Date: Feb. 21, 2013

(54) SOLAR CELL MODULE

(71) Applicants: June-Hyeon AHN, Yongin-si (KR); Kyu-Sub Kwak, Seoul (KR); Ji-Hoon Jung, Seoul (KR); Shin-Hee Cho, Suwon-si (KR)

(72) Inventors: June-Hyeon AHN, Yongin-si (KR); Kyu-Sub Kwak, Seoul (KR); Ji-Hoon Jung, Seoul (KR); Shin-Hee Cho, Suwon-si (KR)

(73) Assignee: Samsung Electronics Co., Ltd., Suwon-si (KR)

(21) Appl. No.: 13/569,852

(22) Filed: Aug. 8, 2012

(30) Foreign Application Priority Data
Aug. 19, 2011 (KR) 10-2011-0082748

(51) Int. Cl. H01L 31/048

(52) U.S. Cl. 136/251

(57) ABSTRACT

A solar cell module includes a window unit integrally formed with a transparent substrate unit, a plurality of solar cells, and an electrode unit electrically connected to the solar cells. The solar cells and the electrode unit are provided in the transparent substrate unit.

### PRIORITY

This application claims priority under 35 U.S.C. §119(a) to a Korean Patent Application filed in the Korean Intellectual Property Office on Aug. 19, 2011 and assigned Serial No. 10-2011-0082748, the contents of which are incorporated herein by reference.

### BACKGROUND OF THE INVENTION

Field of the Invention

The present invention relates to a solar cell module, and more particularly, to a solar cell module in which a window unit is integrated with a transparent substrate unit.

Description of the Related Art

In general, a portable electronic device uses a charged battery pack. The discharge speed of the battery pack is proportional to a time period in which the portable electronic device is used. If the charge of the battery pack depleted, the battery pack should be replaced with another battery pack or charged by a wired charger, a hands-free jack, or a charger cradle.

That is, the use time of the portable electronic device depends on the charging capability of the battery pack. Since the charging capability of the battery pack is limited, the use time is restricted by the few options to charge the battery pack.

For example, to charge the battery pack, a user must inconveniently carry a separate charger, such as a wired charger, a hands-free jack, and a charger cradle all the time.

To avoid the inconvenience of carrying the separate charger, a solar cell module for directly converting solar light to power has been developed. The solar cell module is provided in the portable electronic device, to thereby supply power to the portable electronic device and/or charge the battery pack.

Referring to FIGS. 1 and 2, a solar cell module 1 includes a window 2 formed of tempered glass or transparent acrylic, a transparent substrate 4 having a plurality of solar cells 3 built inside on a bottom surface of the window 2, a Printed Circuit Board (PCB) 5 on a bottom surface of the transparent substrate 4, for electrically connecting the solar cells 3 to one another and to a portable electronic device (not shown), and a reinforcing metal plate 6 on a bottom surface of the PCB 5, for preventing the solar cells 3 and the PCB 5 from being bent or impacted.

A configuration of the solar cell module is disclosed in Korean Patent Publication No. 2005-25657 (Mar. 14, 2005).

When the solar cell module is mounted in a portable electronic device, the solar cell module is carried with the portable electronic device. Therefore, possible impact and deformation of the solar cell module during movement with the portable electronic device is minimized.

Thus, the tempered glass or transparent acrylic window 2 is mounted on a top surface of the solar cell module 1 and the reinforcing metal plate 6 is disposed on a bottom surface of the solar cell module 1, as illustrated in FIG. 2.

However, the use of the PCB and the reinforcing metal plate increases the thickness of the conventional solar cell module, which serves as an obstacle to slimming and miniaturization of the portable electronic device.

If the thick solar cell module is used in the portable electronic device, the thickness of the portable electronic increases. It is thus difficult to slim down and miniaturize the portable electronic device.

Moreover, due to the use of an expensive PCB for electrically connecting a plurality of solar cells to the portable electronic device, the fabrication cost of the conventional solar cell module is high.

As illustrated in FIG. 2, the conventional solar cell module 1 has an air cap

Al between the window 2 and the transparent substrate 4. If solar light C1 is transferred to the solar cell module 1 in this state, the solar light C1 passes through the window 2, the air cap Al, the transparent substrate 4, and then reaches the solar cells 3. Since the solar light C1 goes through a plurality of phases in this manner, the loss of the solar light C1 results in lower power production.

Accordingly, there exists a need for a solar cell module having a window and a transparent substrate integrally formed, with an expensive PCB replaced with another device.

### SUMMARY OF THE INVENTION

An aspect of embodiments of the present invention is to address at least the problems and/or disadvantages and to provide at least the advantages described below. Accordingly, an aspect of embodiments of the present invention is to provide a solar cell module, which can be made thinner, slimmer, and smaller by integrating a window unit with a transparent substrate unit and thus eliminating a conventional air cap.

Another aspect of embodiments of the present invention is to provide a solar cell module having a window unit and a transparent substrate unit integrally formed allowing solar light to pass directly to solar cells without a conventional air cap, thus enhancing transfer of the solar light.

A further aspect of embodiments of the present invention is to provide a solar cell module which can be made thinner, slimmer, and smaller and reduce product fabrication cost by using an electrode unit electrically connected to a plurality of solar cells without a need for an expensive Printed Circuit Board (PCB).

In accordance with an embodiment of the present invention, a solar cell module includes a window unit integrally formed with a transparent substrate unit, a plurality of solar cells, and an electrode unit. The solar cells are divided and their size is determined according to power supply specifications of a portable electronic device. The electrode unit is electrically connected to the solar cells. The solar cells and the electrode unit are provided in the transparent substrate unit. The window unit is attached integrally on a top surface of the transparent substrate unit to protect and reinforce the solar cells, the electrode unit, and the transparent substrate unit.

In accordance with another embodiment of the present invention, a solar cell module includes a window unit integrated with a transparent substrate unit, and an electrode unit electrically connected to a plurality of solar cells and attached together with the solar cells to the transparent substrate unit.

In accordance with another embodiment of the present invention, a portable electronic device includes a window unit integrated with a transparent substrate unit, and an electrode unit electrically connected to a plurality of solar cells and attached together with the solar cells to the transparent substrate unit.

### BRIEF DESCRIPTION OF THE DRAWINGS

The above and other objects, features and advantages of certain embodiments of the present invention will be more apparent from the following detailed description taken in conjunction with the accompanying drawings, in which:

FIG. 1 is a perspective view of a conventional solar cell module;

FIG. 2 is a sectional view of the conventional solar cell module illustrated in FIG. 1, taken along line A-A′;

FIG. 3 illustrates solar cells and an electrode unit in a solar cell module according to an embodiment of the present invention;

FIG. 4 is a side view of the solar cells and the electrode unit in the solar cell module according to an embodiment of the present invention;

FIG. 5 is a perspective view of the solar cell module according to an embodiment of the present invention; and

FIG. 6 is a sectional view of the solar cell module illustrated in FIG. 5, taken along line B-B′.

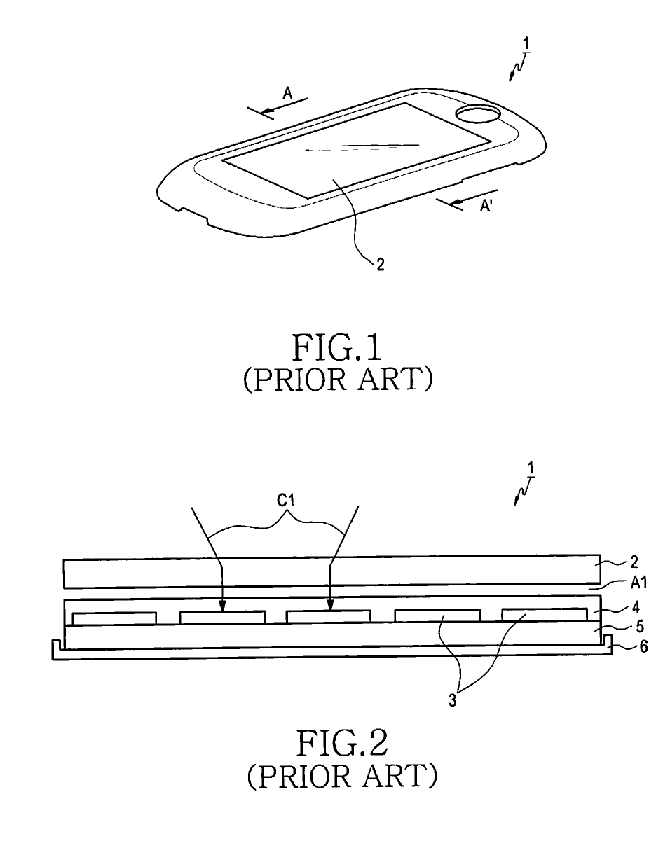

Throughout the drawings, the same drawing reference numerals will be understood to refer to the same elements, features and structures.

### DETAILED DESCRIPTION OF EMBODIMENTS OF THE INVENTION

Reference will now be made in detail to the preferred embodiments of the present invention with reference to the accompanying drawings. In addition, a detailed description of a generally known function and structure of the present invention will be avoided lest it should obscure the subject matter of the present invention.

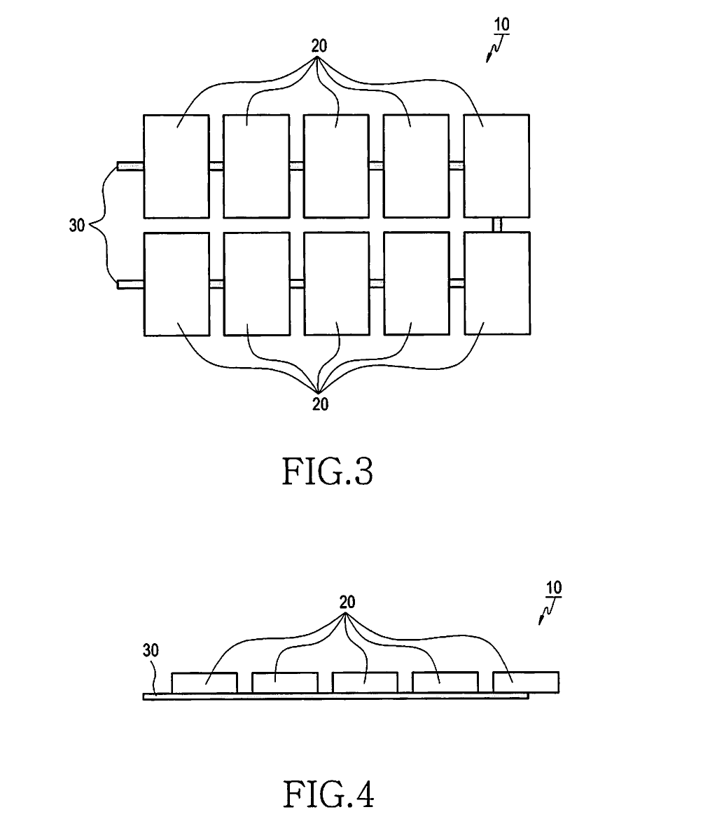

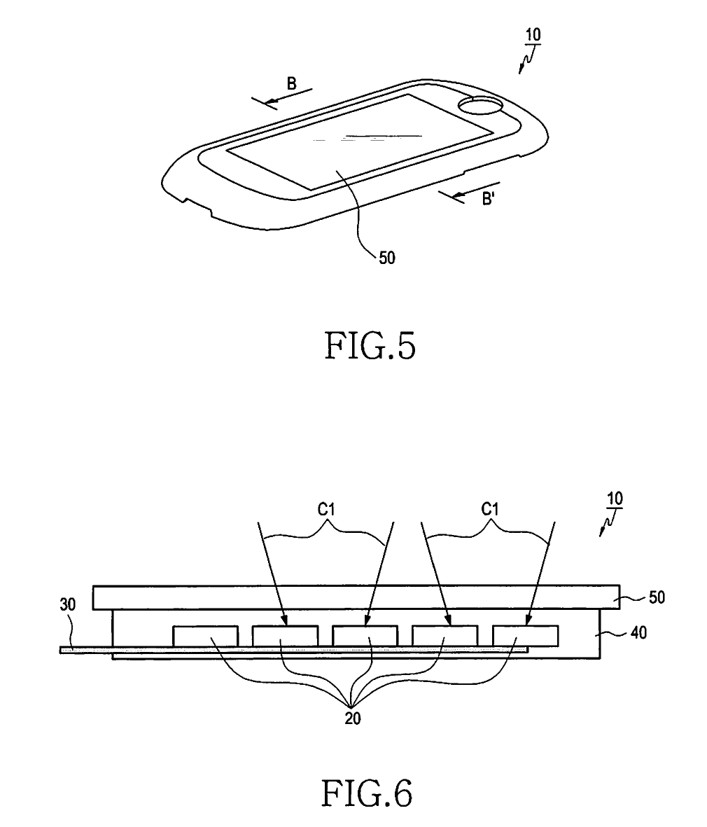

Referring to FIGS. 5 and 6, a solar cell module 10 includes a window unit 50 integrated with a transparent substrate unit 40, a plurality of solar cells 20, and an electrode unit 30. As illustrated in FIGS. 3, 8 to 10 of the solar cells 20 are arranged according to the power specifications of a portable electronic device (not shown). The solar cells 20 are of a rear surface electrode type. Specifically, the solar cells 20 of the rear surface electrode type are arranged on the electrode unit 30 to carry electricity to the electronic unit 30 from a rear surface of the solar cells 20, maximizing absorption of solar light.

The number of the solar cells 20 may be increased or decreased depending on the size and power specifications of the portable electronic device (not shown).

Referring to FIGS. 3 and 4, the electrode unit 30 is provided to electrically connect the solar cells 20 divided suitably for the portable electronic device (not shown). The electrode unit 30 electrically as well as physically connects the solar cells 20 to one another by a tabbing process, or other suitable means. The electrode unit 30 is preferably arranged in a “U” shape, although The electrode unit may also take any other suitable shape, for example, “C”, “L”, etc. The electrode unit 30 is adhered and electronically connected by the tabbing process to the solar cells 20. Adherence of the solar cells 20 completes the tabbing process and the electronic unit 30 includes the transparent substrate unit 40 in a body to the window unit 50. The tabbing process is a heat connection process that modularizes the electrode unit 30 by electronically connecting the electrode unit 30 to the solar cells 20.

Referring to FIG. 6, the solar cells 20 and the electrode unit 30 finished by the tabbing process described above, are mounted in the transparent substrate unit 40 integrally formed with the window unit 50 by lamination.

Referring to FIGS. 5 and 6, one end of the electrode unit 30 protrudes to a predetermined length from a surrounding edge of the transparent substrate unit 40 and is electrically connected to the portable electronic device (not shown).

In an embodiment, the transparent substrate unit 40 is formed of Ethylene Vinyl Acetate (EVA) and the window unit 50 is formed of glass, allowing for the transmission of solar light C1.

In this state, if a user needs to charge a battery pack (not shown) externally mounted to the portable electronic device, the solar light C1 is transmitted to the solar cell module 10 provided in the portable electronic device. The solar light C1 directly reaches the window unit 50 and the transparent substrate unit 40 integrated with the window unit 50. Then, the solar light C1 is transferred directly to the solar cells 20 and the solar cells 20 convert the solar light C1 to electricity. The electricity powers the portable electronic device and charges the battery pack (not shown) built in the portable electronic device, as well.

As is apparent from the above description of the present invention, since the solar cells 20 and the electrode unit 30 are provided in the transparent substrate unit 40 integrated with the window unit 50, formation of a conventional air cap is unnecessary, thus reducing the thickness of the portable electronic device and contributing to slimming down and miniaturization of the portable electronic device.

In addition, as the solar light C1 directly reaches the solar cells 20 through the window unit 50 and the transparent substrate unit 40, the transfer loss of the solar light C1 is minimized and thus the functionality of the portable electronic device is improved.

Moreover, since the conventional PCB is replaced with the electrode unit 30, the absence of the expensive PCB decreases the product thickness and thus further slims down and miniaturizes the product. Therefore, the fabrication cost of the product is reduced.

While a portable electronic device is taken as an example to which the solar cell module 10 is applied in the above embodiment of the present invention, it is to be understood that the solar cell module 10 is not limited to the specific portable electronic device but applicable to any type of portable electronic device using a solar cell module.

The portable electronic device according to the embodiment of the present invention covers a broad range of terminals such as mobile communication terminals conforming to communication protocols of various communication systems, information communication devices including a Portable Multimedia Player (PMP), an MP3 player, a navigator, a game console, a laptop, an advertisement board, a TV, a digital broadcasting player, a Personal Digital Assistant (PDA), a smart phone, multimedia devices, and their applications.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A solar cell module, comprising:
a window unit integrated with a transparent substrate unit;
a plurality of solar cells; and
an electrode unit electrically connected to the solar cells,
wherein the solar cells and the electrode unit are provided in the transparent substrate unit.

2. The solar cell module of claim 1, wherein the solar cells are rear-surface-electrode-type solar cells.

3. The solar cell module of claim 1, wherein the electrode unit is electrically connected to the solar cells by a tabbing process.

4. The solar cell module of claim 1, wherein the solar cells and the electrode unit are provided in the transparent substrate unit by lamination.

5. The solar cell module of claim 1, wherein the transparent substrate unit is formed of Ethylene Vinyl Acetate (EVA).

6. The solar cell module of claim 1, wherein the electrode unit is arranged in a “U” shape.

7. The solar cell module of claim 1, wherein the window unit is formed of glass.

8. The solar cell module of claim 1, wherein the electrode unit is electrically connected to a portable electronic device.

9. A solar cell module, comprising:
a window unit integrated with a transparent substrate unit; and
an electrode unit electrically connected to a plurality of solar cells and attached together with the solar cells to the transparent substrate unit.

10. A portable electronic device, comprising:
a window unit integrated with a transparent substrate unit; and
an electrode unit electrically connected to a plurality of solar cells and attached together with the solar cells to the transparent substrate unit.
